(19) United States
(12) Patent Application Publication
(10) Pub. No.: US 2015/0097161 A1
(43) Pub. Date: Apr. 9, 2015

(54) ORGANIC LIGHT EMITTING DEVICE AND ORGANIC LIGHT EMITTING DISPLAY HAVING THE SAME

(71) Applicant: LG DISPLAY CO., LTD., Seoul (KR)

(72) Inventors: JAE-IL SONG, Paju-si (KR); TAE-SUN YOO, Goyang-si (KR); DONG-HYUK KIM, Gwanak-gu (KR)

(21) Appl. No.: 14/315,052

(22) Filed: Jun. 25, 2014

(30) Foreign Application Priority Data
Oct. 4, 2013 (KR) 10-2013-0118722

(51) Int. Cl. H01L 27/32

(52) U.S. Cl. CPC H01L 27/326
USPC 257/40

(57) ABSTRACT

Disclosed is an organic light emitting device including a first electrode, a second electrode, and an organic laminate formed between the first and second electrodes. The organic laminate includes, a multilayer-light emitting structure that includes two or more light emitting layers emitting light of different colors and a charge transport control layer formed at boundaries between the two or more light emitting layers and controlling the amount of charges transported between the two or more light emitting layer. A first light emitting layer of the two or more light emitting layers is between a hole transport layer and the charge transport control layer and formed of a mixture including a first dopant and a host of a hole transport material. Both a hole transport layer and the charge transport control layer are formed of the same material as the host of the first light emitting layer.

This application claims the benefit of Korean Patent Application No. 10-2013-0118722, filed on Oct. 4, 2013, which is hereby incorporated by reference for all purposes as if fully set forth herein.

### BACKGROUND OF THE INVENTION

1. Field of the Invention

The present invention relates to an organic light emitting device which may improve efficiency, and an organic light emitting display having the same.

2. Discussion of the Related Art

Given the increase of information-based society, the field of displays that visually express electrical information signals has rapidly developed. Thus, various flat display devices to enhance performance, such as slimness, light weight and low power consumption, have been researched.

As examples of flat display devices, there are liquid crystal displays (LCDs), plasma display panels (PDPs), field emission displays (FEDs), electro luminescent displays (ELDs), electro-wetting displays (EWDs), and organic light emitting displays (OLEDs).

Thereamong, an OLED is a display device displaying an image using organic light emitting devices that emit light by themselves.

The organic light emitting device includes first and second electrodes that are opposite to each other, and an organic laminate formed between the first and second electrodes. The organic light emitting device emits light based on a driving current flowing between the first and second electrodes. The organic laminate includes a light emitting layer generating light through recombination of holes and electrons. The organic laminate emits light of different colors according to materials of a dopant that are included in the light emitting layer.

As one method to improve efficiency of the organic light emitting device or to produce white light, a multi-stack structure has been proposed. The multi-stack structure is a structure in which the organic laminate formed between the first and second electrodes includes a plurality of stacks. Here, each stack includes an electron transport layer, a light emitting layer, and a hole transport layer.

FIG. 1 is a cross-sectional view illustrating a related art organic light emitting device having a multi-stack structure.

As shown in FIG. 1, a related art organic light emitting device 10 having a multi-stack structure includes an anode 11 and a cathode 12 opposite to each other, a plurality of stacks 13 and 14 formed between the anode 11 and the cathode 12, a charge generation layer 15 formed between the stacks 13 and 14, a hole injection layer 16 formed between the anode 11 and the plurality of stacks 13 and 14, and an electron injection layer 17 formed between the cathode 12 and the plurality of stacks 13 and 14.

Each of the stacks 13 and 14 includes a hole transport layer (HTL), a light emitting layer (EML), and an electron transport layer (ETL).

The charge generation layer 15 is formed in a multi-layered structure including at least two of metals, oxides, and organic matters so as to generate holes and electrons which will be transported to the plurality of stacks 13 and 14.

That is, the charge generation layer 15 serves as a cathode injecting electrons into the stack 13 which is closer to the anode 11 then the other stack 14. Also, the charge generation layer 15 serves as an anode injecting holes into the stack 14 which is closer than the cathode 12 then the stack 13.

The organic light emitting device 10 having a multi-stack structure includes a large number of light emitting layers and may thus have an advantage of increasing efficiency, as compared to an organic light emitting device having a mono structure including one stack. However, the organic light emitting device 10 having the multi-stack structure includes a large number of interlayer boundaries and may thus have disadvantages of high driving voltage and short lifespan.

### SUMMARY OF THE INVENTION

Accordingly, the present invention is directed to an organic light emitting device and an organic light emitting display having the same that substantially obviate one or more problems due to limitations and disadvantages of the related art.

An advantage of the present invention is to provide an organic light emitting device which includes a plurality of light emitting layers in order to improve efficiency and decrease driving voltage in order to increase lifespan of the device.

Additional advantages, and features of the invention will be set forth in part in the description which follows and in part will become apparent to those having ordinary skill in the art upon examination of the following or may be learned from practice of the invention. These and other advantages of the invention may be realized and attained by the structure particularly pointed out in the written description and claims hereof as well as the appended drawings.

To achieve these and other advantages and in accordance with the purpose of the invention, as embodied and broadly described herein, an organic light emitting device includes a first electrode connected to a thin film transistor formed on a substrate, a second electrode being opposite to the first electrode, and an organic laminate formed between the first electrode and the second electrode and including a hole transport layer, a multilayer-light emitting structure, and an electron transport layer.

Here, the multilayer-light emitting structure includes two or more light emitting layers emitting light of different colors through recombination of electrons and holes injected through the first and second electrodes and a charge transport control layer formed on one or more boundaries between the two or more light emitting layers and controlling the amount of charges transported between the two or more light emitting layers.

Among the two or more light emitting layers, a first light emitting layer disposed between the hole transport layer and the charge transport control layer is formed of a mixture including a first dopant and a host of a hole transport material corresponding to the first dopant, and the hole transport layer and the charge transport control layer are formed of the same material as the host of the first light emitting layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional view illustrating a related art organic light emitting device having a multi-stack structure;

FIG. 2 is a cross-sectional view illustrating a part of an organic light emitting display in accordance with one embodiment of the present invention;

FIG. 3 is a cross-sectional view illustrating an organic light emitting device of FIG. 2;

FIG. 4 is a cross-sectional view illustrating an organic laminate shown in FIG. 3 in accordance with one embodiment of the present invention;

FIG. 5 is a band diagram of the organic laminate in accordance with the embodiment of the present invention;

FIG. 6 is a cross-sectional view illustrating an organic laminate shown in FIG. 3 in accordance with another embodiment of the present invention; and

FIG. 7 is a band diagram of the organic laminate in accordance with the embodiment of the present invention.

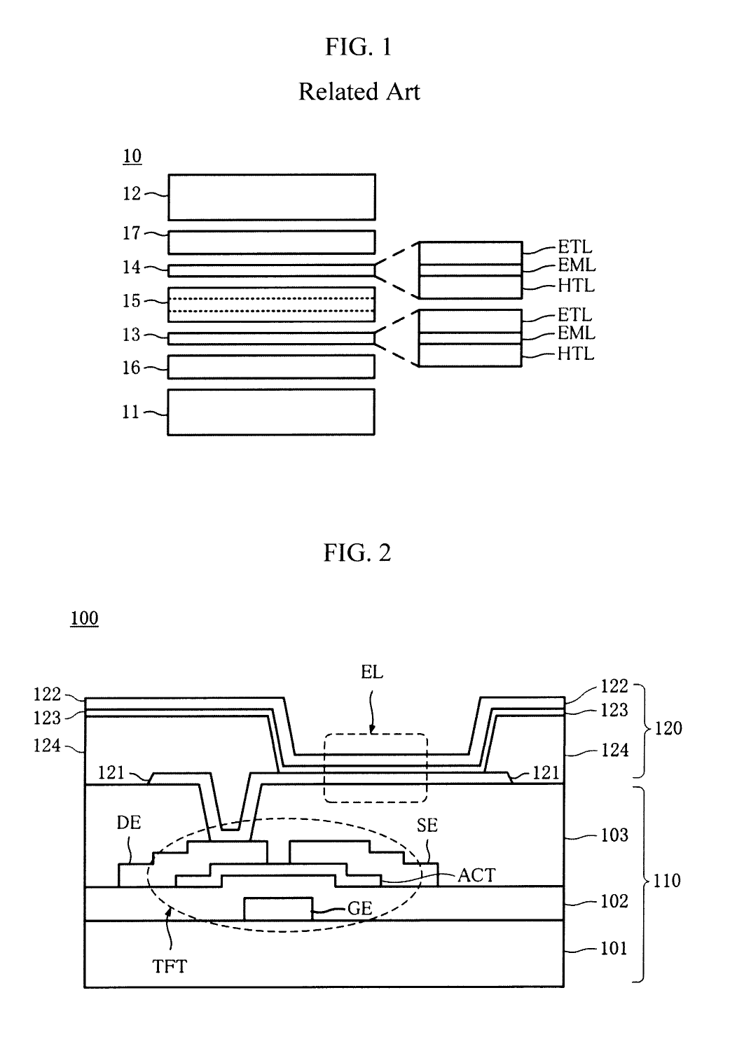

### DETAILED DESCRIPTION OF THE INVENTION

Reference will now be made in detail to embodiments of the present invention, examples of which are illustrated in the accompanying drawings. Wherever possible, the same reference numbers will be used throughout the drawings to refer to the same or like parts.

Hereinafter, an organic light emitting device and an organic light emitting display having the same in accordance with one embodiment of the present invention will be described with reference to the accompanying drawings.

First, with reference to FIGS. 2 to 5, an organic light emitting display and an organic light emitting device included therein in accordance with one embodiment of the present invention will be described.

As shown in FIG. 2, an organic light emitting display 100 in accordance with one embodiment of the present invention includes a thin film transistor array substrate (hereinafter, “TFT array substrate”) 110 and an organic light emitting device array 120 formed on the TFT array substrate 110.

Although not shown in the drawings, the TFT array substrate 110 includes gate lines (not shown) and data lines (not shown) formed in directions crossing each other so as to define a plurality of pixel areas, and thin film transistors TFTs formed at crossing areas between the gate lines and the data lines and corresponding to the respective pixel areas.

Each of the thin film transistors TFTs includes a gate electrode GE formed on a substrate 101, a gate insulating film 102 formed on the substrate 101 and covering the gate electrode GE, an active layer ACT formed on the gate insulating film 102 and at least partially overlapping the gate electrode GE, and a source electrode SE and a drain electrode DE formed on the gate insulating layer 102 so as to be separated from each other and contacting both sides of the active layer ACT.

The thin film transistor TFT is covered with a protective film 103 formed on the gate insulating layer 102.

The organic light emitting device array 120 includes organic light emitting devices EL corresponding to the respective pixel areas. The organic light emitting device EL includes a first electrode 121 formed at each pixel area on the protective layer 103, a second electrode 122 being opposite to the first electrode 121, and an organic laminate 123 formed between the first and second electrodes 121 and 122.

For example, the organic light emitting device array 120 may include first electrodes 121 formed at the respective pixel areas on the protective layer 103, banks BK 124 formed at the outsides of the respective pixel areas on the protective layer 103 and overlapping the edges of the respective first electrodes 121, the organic laminate 123 formed on the first electrodes 121, and the second electrode 122 formed on the whole upper surface of the organic laminate 123.

The first electrode 121 is connected to any one of the source electrode SE and the drain electrode DE of the thin film transistor TFT, which is not connected to the data line (not shown).

Further, any one of the first and second electrodes 121 and 122 which is opposite to an image display surface may be formed of a reflective metal material, and the other may be formed of a transparent conductive material.

Otherwise, although not shown in the drawings, both of the first and second electrodes 121 and 122 may be formed of a transparent conductive material and the organic light emitting device array 120 may further include a reflective film which is opposite to the image display surface.

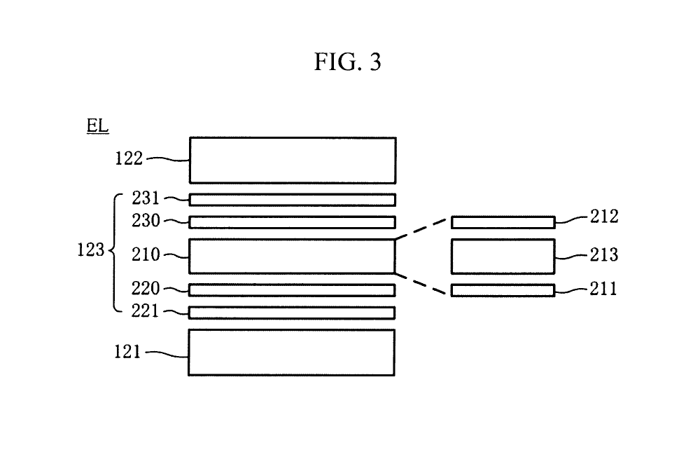

As shown in FIG. 3, the organic light emitting device EL includes the first and second electrodes 121 and 122 which are opposite to each other and the organic laminate 123 formed between the first and second electrodes 121 and 122 and including a multilayer-light emitting structure 210.

If the first electrode 121 is an anode and the second electrode 122 is a cathode, the organic laminate 123 further includes a hole transport layer 220 formed of a hole transport material between the first electrode 121 and the multilayer-light emitting structure 210 and an electron transport layer 230 formed of an electron transport material between the multilayer-light emitting structure 210 and the second electrode 122.

The organic laminate 123 may further include at least one of a hole injection layer 221 formed of a hole injection material between the first electrode 121 and the hole transport layer 220 and an electron injection layer 231 formed of an electron injection material between the second electrode 122 and the electron transport layer 230.

The multilayer-light emitting structure 210 includes two or more light emitting layers 211 and 212 emitting light using extra energy discharged by change of exitons, generated through recombination of electrons and holes injected from the first and second electrodes 121 and 122, from an excited state to a ground state and a charge transport control layer 213 formed between the respective light emitting layers 211 and 212.

The two or more light emitting layers 211 and 212 may be formed of materials including different light emitting dopants and thus emit light of different colors.

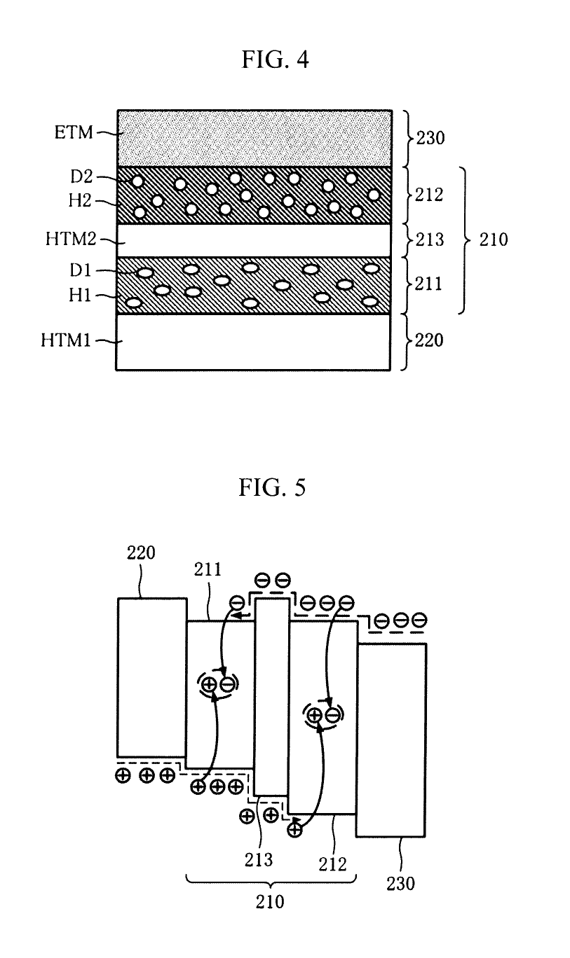

That is, as exemplarily shown in FIG. 4, if the multilayer-light emitting structure 210 includes first and second light emitting layers 211 and 212, the first light emitting layer 211 is formed of an organic light emitting material including a first light emitting dopant D1 corresponding to a first color and a first host H1 corresponding to the first light emitting dopant D1. Further, the second light emitting layer 212 is formed of an organic light emitting material including a second light emitting dopant D2 corresponding to a second color different from the first color and a second host H2 corresponding to the second light emitting dopant D2.

For example, the first dopant D1 of the first light emitting layer 211 may be a red dopant and the second dopant D2 of the second light emitting layer 212 may be a blue dopant.

In general, host suitable for a light emitting dopant may be used as an electron transport material. That is, the first and second hosts H1 and H2 of the first and second light emitting layers 211 and 212 may be electron transport materials.

Further, as described above, the hole transport layer 220 is formed of a hole transport material (HTM1) and the electron transport layer 230 is formed of an electron transport material (ETM).

Here, although the electron transport layer 230 and the first and second hosts H1 and H2 are generally formed of different electron transport materials (ETMs), the electron transport layer 230 and the first and second hosts H1 and H2 may be formed of the same electron transport material (ETM).

For example, as electron transport materials selected as the electron transport layer 230 and the first and second hosts H1 and H2, NPB(N,N′-bis(naphthalen-1-yl)-N,N′-bis(phenyl)-benzidine), β-NPB(N,N′-bis(naphthalen-2-yl)-N,N′-bis(phenyl)-benzidine), TPD(N,N′-bis(3-methylphenyl)-N,N′-bis(phenyl)-benzidine), spiro-TPD(N,N′-bis(3-methylphenyl)-N,N′-bis(phenyl)-2,7-diamino-9,9-spirobifluorene), spiro-NPB(N,N′-bis(naphthalen-1-yl)-N,N′-bis(phenyl)-2,7-diamino-9,9-spirobifluorene), DMFL-TPD(N,N′-bis(3-methylphenyl)-N,N′-bis(phenyl)-2,7-diamino-9,9-dimethyl-fluorene), DMFL-NPD(N,N′-bis(naphthalen-1-yl)-N,N′-bis(phenyl)-2,7-diamino-9,9-dimethyl-fluorene), DPFL-TPD(N,N′-bis(3-methylphenyl)-N,N′-bis(phenyl)-2,7-diamino-9,9-diphenyl-fluorene), DPFL-NPB(N,N′-bis(naphthalen-1-yl)-N,N′-bis(phenyl)-2,7-diamino-9,9-diphenyl-fluorene), α-NPD(N,N′-bis(naphthalen-1-yl)-N,N′-bis(phenyl)-2,2′-dimethylbenzidine), spiro-TAD(2,2′,7,7′-tetrakis(N,N-diphenylamino)-9,9-spirobifluorene), NPAPF(9,9-bis[4-(N,N-bis-naphthalen-2-yl-amino)phenyl]-9H-fluorene), NPBAPF(9,9-bis[4-(N-naphthalen-1-yl-N-phenylamino)-phenyl]-9H-fluorene), spiro-2NPB(2,2′,7,7′-tetrakis[N-naphthalenyl(phenyl)-amino]-9,9-spirobifluorene), PAPB(N,N′-bis(phenanthren-9-yl)-N,N′-bis(phenyl)-benzidine), 2,2′-spiro-DBP(2,2′-bis[N,N-bis(biphenyl-4-yl)amino]-9,9-spirobifluorene), spiro-BPA(2,2′-bis(N,N-di-phenyl-amino)-9,9-spirobifluorene), TAPC(Di-[4-(N,N-ditolyl-amino)-phenyl]cyclohexane), spiro-TTB(2,2′,7,7′-tetra(N,N-ditolyl)amino-9,9-spiro-bifluorene), β-TNB(N,N,N′,N′-tetra-naphthalen-2-yl-benzidine), HMTPD(N,N,N′,N′-tetra-(3-methylphenyl)-3,3′-dimethylbenzidine), α,β-TNB(N,N′-di(naphthalenyl)-N,N′-di(naphthalen-2-yl)-benzidine), α-TNB(N,N,N′,N′-tetra-naphthalenyl-benzidine), β-NPP(N,N′-di(naphthalen-2-yl)-N,N′-diphenylbenzene-1,4-diamine), TTP(N1,N4-diphenyl-N1,N4-dim-tolylbenzene-1,4-diamine), NDDP(N2,N2,N6,N6-tetraphenylnaphthalen-2,6-diamine), TQTPA(Tris(4-(quinolin-8-yl)phenyl)amine), 3DTAPBP(2,2′-bis(3-(N,N-di-p-tolylamino)phenyl)biphenyl), TFB(Poly[9,9-dioctylfluorenyl-2,7-diyl)-co-(4,4′-(N-(4-sec-butylphenyl)diphenylamine)]), Poly-TPD(Poly[N,N′-bis(4-butylphenyl)-N,N′-bis(phenyl)-benzidine]), DBTPB(N4,N4′-bis(dibenzo[b,d]thiophen-4-yl)-N4,N4′-diphenylbiphenyl-4,4′-diamine), DOFL-NPB(N2,N7-di(naphthalen-1-yl)-9,9-dioctyl-N2,N7-diphenyl-9H-fluorene-2,7-diamine), DOFL-TPD(N,N′-bis(3-methylphenyl)-N,N′-bis(phenyl)-9,9-dioctyl-fluorene), VNPB(N4,N4′-di(naphthalen-1-yl)-N4,N4′-bis(4-vinylphenyl)biphenyl-4,4′-diamine), ONPB(N4,N4′-bis(4-(6-((3-ethyloxetan-3-yl)methoxy)hexyl)phenyl)-N4,N4′-diphenylbiphenyl-4,4′-diamine), OTPD(N4,N4′-bis(4-(6-((3-ethyloxetan-3-yl)methoxy)hexyl)phenyl)-N4,N4′-diphenylbiphenyl-4,4′-diamine), and QUPD(N4,N4′-bis(4-(6-((3-ethyloxetan-3-yl)methoxy)hexyl)phenyl)-N4,N4′-bis(4-methoxyphenyl)biphenyl-4,4′-diamine) may be used.

The two or more light emitting layers 211 and 212 are formed of organic light emitting materials including the first and second hosts H1 and H2, i.e., electron transport materials, and thus, holes are transported at a lower transport degree than electrons between the two or more light emitting layers 211 and 212.

That is, the first light emitting layer 211 is the closest one of the two or more light emitting layers 211 and 212 to the first electrode 121. Thus, an amount of holes transported to residual light emitting layers of the two or more light emitting layers 211 and 212, except for the first light emitting layer 211, i.e., the second light emitting layer 212, is remarkably smaller than an amount of holes transported to the first light emitting layer 211. In other words, the second light emitting layer 212, which is the residual light emitting layer of the two or more light emitting layers 211 and 212 except for the first light emitting layer 211, is more distant from the first electrode 121 than the first light emitting layer 211. Accordingly, efficiency of the residual light emitting layers of the two or more light emitting layers 211 and 212, except for the first light emitting layer 211 is less than efficiency of the first light emitting layer 211. Thus, efficiency of the device is decreased.

Therefore, the multilayer-light emitting structure 210 in accordance with this embodiment of the present invention includes the charge transport control layer 213 formed of a hole transport material (HTM2) on boundaries between the two or more light emitting layers 211 and 212 and controlling the amounts of charges, particularly, the transport degrees of holes, transported between the two or more light emitting layers 211 and 212.

Here, the hole transport layer 220 and the charge transport control layer 213 may be formed of different hole transport materials (HTM1 and HTM2).

For example, as the hole transport materials (HTM1 and HTM2) selected as the hole transport layer 220 and the charge transport control layer 213, NPB(N,N′-bis(naphthalen-1-yl)-N,N′-bis(phenyl)-benzidine), β-NPB(N,N′-bis(naphthalen-2-yl)-N,N′-bis(phenyl)-benzidine), TPD(N,N′-bis(3-methylphenyl)-N,N′-bis(phenyl)-benzidine), spiro-TPD(N,N′-bis(3-methylphenyl)-N,N′-bis(phenyl)-2,7-diamino-9,9-spirobifluorene), spiro-NPB(N,N′-bis(naphthalen-1-yl)-N,N′-bis(phenyl)-2,7-diamino-9,9-spirobifluorene), DMFL-TPD(N,N′-bis(3-methylphenyl)-N,N′-bis(phenyl)-2,7-diamino-9,9-dimethyl-fluorene), DMFL-NPD(N,N′-bis(naphthalen-1-yl)-N,N′-bis(phenyl)-2,7-diamino-9,9-dimethyl-fluorene), DPFL-TPD(N,N′-bis(3-methylphenyl)-N,N′-bis(phenyl)-2,7-diamino-9,9-diphenyl-fluorene), DPFL-NPB(N,N′-bis(naphthalen-1-yl)-N,N′-bis(phenyl)-2,7-diamino-9,9-diphenyl-fluorene), α-NPD(N,N′-bis(naphthalen-1-yl)-N,N′-bis(phenyl)-2,2′-dimethylbenzidine), spiro-TAD(2,2′,7,7′-tetrakis(N,N-diphenylamino)-9,9-spirobifluorene), NPAPF(9,9-bis[4-(N,N-bis-naphthalen-2-yl-amino)phenyl]-9H-fluorene), NPBAPF(9,9-bis[4-(N-naphthalen-1-yl-N-phenylamino)-phenyl]-9H-fluorene), spiro-2NPB(2,2′,7,7′-tetrakis[N-naphthalenyl(phenyl)-amino]-9,9-spirobifluorene), PAPB(N,N′-bis(phenanthren-9-yl)-N,N′-bis(phenyl)-benzidine), 2,2′-spiro-DBP(2,2′-bis[N,N-bis(biphenyl-4-yl)amino]-9,9-spirobifluorene), spiro-BPA(2,2′-bis(N,N-di-phenyl-amino)-9,9-spirobifluorene), TAPC(Di-[4-(N,N-ditolyl-amino)-phenyl]cyclohexane), spiro-TTB(2,2′,7,7′-tetra(N,N-ditolyl)amino-9,9-spiro-bifluorene), β-TNB(N,N,N′,N′-tetra-naphthalen-2-yl-benzidine), HMTPD(N,N,N′,N′-tetra-(3-methylphenyl)-3,3′-dimethylbenzidine), α,β-TNB(N,N′-di(naphthalenyl)-N,N′-di(naphthalen-2-yl)-benzidine), α-TNB(N,N,N′,N′-tetra-naphthalenyl-benzidine), β-NPP(N,N′-di(naphthalen-2-yl)-N,N′-diphenylbenzene-1,4-diamine), TTP(N1,N4-diphenyl-N1,N4-dim-tolylbenzene-1,4-diamine), NDDP(N2,N2,N6,N6-tetraphenylnaphthalen-2,6-diamine), TQTPA(Tris(4-(quinolin-8-yl)phenyl)amine), 3DTAPBP(2,2′-bis(3-(N,N-di-p-tolylamino)phenyl)biphenyl), TFB(Poly[9,9-dioctylfluorenyl-2,7-diyl)-co-(4,4′-(N-(4-sec-butylphenyl)diphenylamine)]), Poly-TPD(Poly[N,N′-bis(4-butylphenyl)-N,N′-bis(phenyl)-benzidine]), DBTPB(N4,N4′-bis(dibenzo[b,d]thiophen-4-yl)-N4,N4′-diphenylbiphenyl-4,4′-diamine), DOFL-NPB(N2,N7-di(naphthalen-1-yl)-9,9-dioctyl-N2,N7-diphenyl-9H-fluorene-2,7-diamine), DOFL-TPD(N,N′-bis(3-methylphenyl)-N,N′-bis(phenyl)-9,9-dioctyl-fluorene), VNPB(N4,N4′-di(naphthalen-1-yl)-N4,N4′-bis(4-vinylphenyl)biphenyl-4,4′-diamine), ONPB(N4,N4′-bis(4-(6-((3-ethyloxetan-3-yl)methoxy)hexyl)phenyl)-N4,N4′-diphenylbiphenyl-4,4′-diamine), OTPD(N4,N4′-bis(4-(6-((3-ethyloxetan-3-yl)methoxy)hexyl)phenyl)-N4,N4′-diphenylbiphenyl-4,4′-diamine), and QUPD(N4,N4′-bis(4-(6-((3-ethyloxetan-3-yl)methoxy)hexyl)phenyl)-N4,N4′-bis(4-methoxyphenyl)biphenyl-4,4′-diamine) may be used.

As described above, by interposing a single charge transport control layer 213 formed of the hole transport material (HTM) on boundaries between the two or more light emitting layers 211 and 212, the transport degree of holes between the two or more light emitting layers 211 and 212 may be improved. Therefore, the amount of holes supplied from the first electrode 121 and transported to the second light emitting layer 212 may be increased, and lowering of efficiency of the second light emitting layer 212 may be prevented. Thus, efficiency of the device is improved.

In accordance with this embodiment, the first light emitting layer 211 including the first host H1 which is an electron transport material is interposed between the hole transport layer 220 and the charge transport control layer 213 formed of hole transport materials (HTM1 and HTM2).

Thereby, as exemplarily shown in FIG. 5, an energy level is rapidly changed at the boundary between the hole transport layer 220 and the first light emitting layer 211 and the boundary between the first light emitting layer 211 and the charge transport control layer 213. Particularly, an energy barrier is generated at the boundary between the first light emitting layer 211 and the charge transport control layer 213 and thus limits in lowering of driving voltage and efficiency improvement.

Therefore, in an organic light emitting device EL in accordance with another embodiment of the present invention, the closest one of the two or more light emitting layer to the hole transport layer includes a host which is selected from a hole transport material suitable for a light emitting dopant, and both of the hole transport layer and the charge transport control layer are formed of the hole transport material which is selected as the host of the closest one of the two or more light emitting layer.

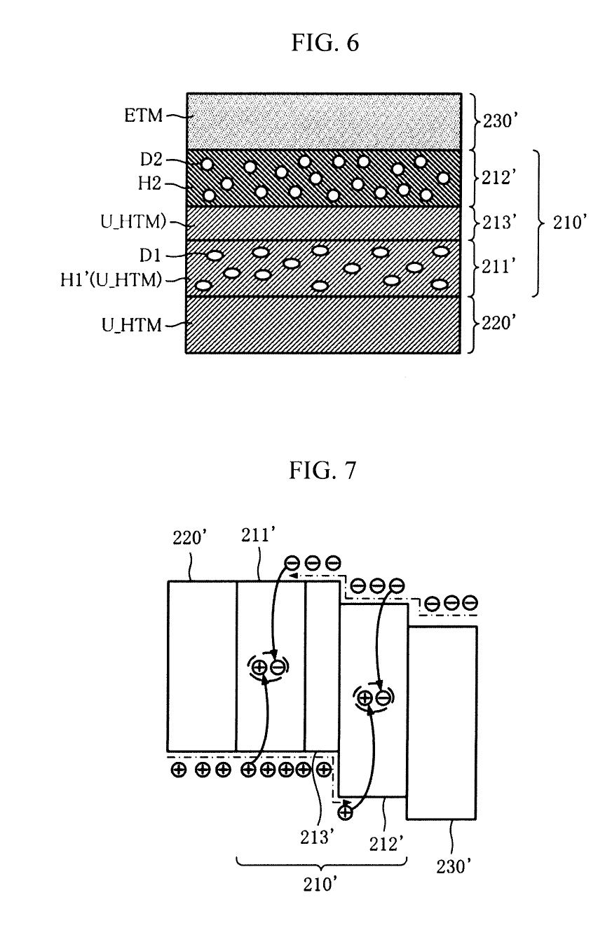

FIG. 6 is a cross-sectional view illustrating an organic laminate shown in FIG. 3 in accordance with another embodiment of the present invention and FIG. 7 is a band diagram of the organic laminate in accordance with the embodiment of the present invention.

As exemplarily shown in FIG. 6, the organic light emitting device EL in accordance with this embodiment of the present invention is the same as the organic light emitting device EL in accordance with the former embodiment of the present invention shown in FIGS. 2 to 5 except that the hole transport layer 220′, a first host H1′ of the first light emitting layer 211′ and the charge transport control layer 213′ are formed of the same hole transport material, and a detailed description of a part of the construction and operation of this embodiment are substantially the same as those of the former embodiment shown in FIGS. 2 to 5 will be omitted because it is considered to be unnecessary.

An organic laminate 123 in accordance with this embodiment of the present invention includes the hole transport layer 220′, a multilayer-light emitting structure 210′, and an electron transport layer 230′.

The multilayer-light emitting structure 210′ includes two or more light emitting layers 211′ and 212′ emitting light of different colors and the charge transport control layer 213′ formed at boundaries between the two or more light emitting layers 211′ and 212′.

The first light emitting layer 211′ of the two or more light emitting layers 211′ and 212′ is disposed between the hole transport layer 220′ and the charge transport control layer 213′ and formed of an organic light emitting material including the first dopant D1 and a first host H1′. In this regard, the first dopant D1 corresponds to the first color. The first host H1′ is a hole transport material (U_HTM), but also corresponds to the first dopant D1.

Like the former embodiment, the remainder of the two or more light emitting layers 211′ and 212′ except for the first light emitting layer 211′, i.e., the second light emitting layer 212′, is formed of the organic light emitting material including the second dopant D2 and the second host H2. The second dopant D2 corresponds to a second color differing from the first color. The second host H2 corresponds to the second dopant D2.

For example, the first dopant D1 of the first light emitting layer 211′ may be a red dopant and the second dopant D2 of the second light emitting layer 212′ may be a blue dopant.

The charge transport control layer 213′ is formed of the same hole transport material (U_HTM) as the first host H1′ of the first light emitting layer 211′.

Further, the hole transport layer 220′ is formed of the same hole transport material (U_HTM) as the first host H1′ of the first light emitting layer 211′.

In other words, the hole transport layer 220′, the first host H1′ of the first light emitting layer 211′, and the charge transport control layer 213′ are formed of the same hole transport material (U_HTM). Therefore, as exemplarily shown in FIG. 7, the energy levels of the hole transport layer 220′, the first light emitting layer 211′, and the charge transport control layer 213′ become similar. Thus, an energy barrier at boundaries between the hole transport layer 220′, the first light emitting layer 211′, and the charge transport control layer 213′ may be removed. Thereby, driving voltage may be decreased, and thus, efficiency and lifespan of the device may be improved, as compared to the former embodiment shown in FIGS. 2 to 5.

Table 1 below states comparison between characteristics of the organic light emitting device in accordance with the embodiment 1 shown in FIGS. 2 to 5 and the organic light emitting device in accordance with the embodiment 2 shown in FIGS. 6 and 7.

TABLE 1

| | Driving voltage (V) | cd/A | EQE (efficiency) |
|---|---|---|---|
| Embodiment 1 | 1.0 | 1.0 | 1.0 |
| Embodiment 2 | 0.9 | 1.0 | 1.1 |

As stated in Table 1, it may be understood that the organic light emitting device in accordance with the embodiment 2 shown in FIGS. 6 and 7 may be driven at driving voltage reduced by 0.1V and exhibit efficiency increased by 0.1, as compared to the organic light emitting device in accordance with the embodiment 1 shown in FIGS. 2 to 5.

As described above, the organic light emitting devices (ELs) in accordance with the respective embodiments of the present invention include the two or more light emitting layers 211 and 212 emitting light of different colors and may thus improve efficiency and efficiently produce white light.

Further, differing from a related art organic light emitting device having a multi-stack structure, the organic light emitting devices in accordance with the embodiments of the present invention do not interpose a charge generation layer, an electron transport layer, and a hole transport layer on boundaries between the two or more light emitting layers 211 and 212, but interpose the single charge transport control layer either 213 or 213′ formed of a material including a hole transport material on boundaries between the two or more light emitting layers 211 and 212.

Thereby, the organic light emitting devices in the embodiments of the present invention may reduce the number of interlayer boundaries, as compared to the related art organic light emitting device having a multi-stack structure, and thus lower driving voltage. That is, the organic light emitting devices in the embodiments of the present invention may be driven at a lower voltage and thus, the lifespan of the organic light emitting devices may be improved, as compared to the related art organic light emitting device having a multi-stack structure.

Further, since holes injected from the first electrode 121 may be transported between the two or more light emitting layers 211 and 212 including hosts of electron transport materials at improved transport degree, it may be prevented that efficiency of the second light emitting layer 212 being more distant from the first electrode 121 than the first light emitting layer 211, is decreased.

Particularly, in accordance with the embodiment shown in FIGS. 6 and 7, the hole transport layer 220′, the first host H1 of the first light emitting layer 211′, and the charge transport control layer 213′ are formed of the same hole transport material. Thus, an energy barrier at each of the boundaries among the hole transport layer 220′, the first host H1 of the first light emitting layer 211′, and the charge transport control layer 213′ may be removed and driving voltage may be more lowered. Thereby, efficiency and lifespan of the device may be improved.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. An organic light emitting device, comprising:
a first electrode respectively connected to a thin film transistor formed on a substrate;
a second electrode arranged opposite to the first electrode; and
an organic laminate formed between the first electrode and the second electrode and including a hole transport layer, a multilayer-light emitting structure, and an electron transport layer, wherein the multilayer-light emitting structure includes:
two or more light emitting layers emitting light of different colors through recombination of electrons and holes injected through the first and second electrodes; and
a charge transport control layer formed at boundaries between the two or more light emitting layers and controlling the amount of charges transported between the two or more light emitting layers, wherein:
a first light emitting layer of the two or more light emitting layers is disposed between the hole transport layer and the charge transport control layer and formed of a mixture including a first dopant and a host of a hole transport material corresponding to the first dopant; and
both the hole transport layer and the charge transport control layer are formed of the same material as the host of the first light emitting layer.

2. The organic light emitting device according to claim 1, wherein, a second light emitting layer of the two or more light emitting layers is closer to the electron transport layer and formed of a mixture including a second dopant and a host corresponding to the second dopant.

3. The organic light emitting device according to claim 2, wherein:
the first dopant of the first light emitting layer is a red dopant; and
the second dopant of the second light emitting layer is a blue dopant.

4. The organic light emitting device according to claim 1, wherein the organic laminate further includes:
a hole injection layer formed of a hole injection material between the first electrode and the hole transport layer; and
an electron injection layer formed of an electron injection material between the second electrode and the electron transport layer.

5. An organic light emitting display including the organic light emitting device according to claim 1, the organic light emitting display comprising:
a thin film transistor array substrate including a thin film transistor;
an organic light emitting device array including the organic light emitting device, wherein the organic light emitting device array is formed on the thin film transistor array substrate,
wherein the organic light emitting device corresponds to pixel areas of the thin film transistor array substrate,
wherein the organic light emitting device array comprises:
a first electrode arranged on a protective layer of the thin film transistor array substrate and connected to one of a source and drain electrode of the thin film transistor;
a bank layer formed outside the pixel areas and on and overlapping edges of the first electrode;
the organic laminate on the bank layer; and
a second electrode on an entire upper surface of the organic laminate.
